(19) United States
(12) Patent Application Publication
(10) Pub. No.: US 2025/0040162 A1
(43) Pub. Date: Jan. 30, 2025

(54) SEMICONDUCTOR DEVICE AND METHOD OF MANUFACTURING THE SAME

(71) Applicant: Renesas Electronics Corporation, Tokyo (JP)

(72) Inventor: Hitoshi MATSUURA, Tokyo (JP)

(21) Appl. No.: 18/775,122

(22) Filed: Jul. 17, 2024

(30) Foreign Application Priority Data
Jul. 26, 2023 (JP) 2023-121670

(51) Int. Cl. H01L 29/739; H01L 29/10; H01L 29/66

(52) U.S. Cl. CPC H01L 29/7397; H01L 29/1095; H01L 29/66348

(57) ABSTRACT

A semiconductor device including an IGBT with improved switching characteristics is provided. Inside trenches formed inside a semiconductor substrate of an active cell, a trench gate electrode and a trench emitter electrode are formed through a gate insulating film. An n-type hole barrier region is formed inside the semiconductor substrate located between the trenches. A p-type base region is formed inside the hole barrier region. An n-type emitter region is formed inside the base region. A p-type floating region is formed inside the semiconductor substrate of an inactive cell. A depth of the floating region is shallower than each depth of the trenches, and is deeper than a depth of the base region.

### CROSS-REFERENCE TO RELATED APPLICATIONS

The disclosure of Japanese Patent Application No. 2023-121670 filed on Jul. 26, 2023, including the specification, drawings and abstract is incorporated herein by reference in its entirety.

### BACKGROUND

The present invention relates to a semiconductor device and a method of manufacturing the same, and more particularly, to a semiconductor device equipped with a gate electrode formed inside a trench and a method of manufacturing the same.

In recent years, semiconductor devices equipped with power semiconductor elements such as IGBT (Insulated Gate Bipolar Transistor) have been widely used. Also, IGBTs with low on-resistance, each of which uses a structure including a gate electrode embedded inside a trench, have been known.

There are disclosed techniques listed below.
[Patent Document 1] Japanese Unexamined Patent Application Publication No. 2013-140885
[Patent Document 2] Japanese Unexamined Patent Application Publication No. 2017-157733

For example, in Patent Document 1, an IGBT with a GGEE structure and an EGE structure utilizing the IE (Injection Enhancement) effect is disclosed. The IE effect is a technique to increase the concentration of charge accumulated in the drift region by making it difficult to discharge holes to the emitter wiring EW side when the IGBT is in the on state.

Note that the “G” in the GGEE structure means a trench gate electrode that is embedded inside a trench through a gate insulating film and is connected to a gate potential. The “E” in the GGEE structure means a trench emitter electrode that is embedded inside a trench through a gate insulating film and is connected to an emitter potential. Therefore, the GGEE structure is a structure in which a pair of trench emitter electrodes are formed at a certain distance from a pair of trench gate electrodes.

Also, in Patent Document 2, an IGBT with a GGEEs structure in which the cell pitch of the GGEE structure is shrunk is disclosed. In the GGEEs structure, a distance between a pair of trench emitter electrodes is shorter than a distance between a pair of trench gate electrodes, and the trench emitter electrode and a base region are connected by the same hole. That is, the “s” in the GGEEs structure means that the distance between the pair of trench emitter electrodes is shrunk.

### SUMMARY

The IGBT with the GGEE structure is used in, for example, an inverter that requires a large current. In this case, the saturation current density cannot be increased more than necessary, in order to ensure load short-circuit tolerance. Also, in the design of this IGBT, emphasis is placed on reducing the on-voltage by promoting conductivity modulation without increasing the MOSFET (Metal Oxide Semiconductor Field Effect Transistor) component.

On the other hand, IGBTs for PFC (Power Factor Correction) applications are used in products such as air conditioners. In the IGBT for PFC applications, it is important to increase the switching speed and reduce the switching loss. Also, since the priority for ensuring load short-circuit tolerance is low, the saturation current density can be increased.

If the IGBT for PFC applications can be manufactured using the GGEE structure manufacturing process, the development period can be shortened, new manufacturing equipment is not required, and manufacturing costs can be reduced. In that case, it is necessary to design the IGBT to maintain a low on-voltage and to increase the switching speed and reduce the switching loss.

The main purpose of this application is to provide a semiconductor device with an IGBT with improved switching characteristics. Other problems and novel features will become apparent from the description and attached drawings of this specification.

The typical ones of the embodiments disclosed in the present application will be briefly described as follows.

A semiconductor device according to one embodiment includes: a semiconductor substrate of a first conductive type having an upper surface and a lower surface opposite to the upper surface; a first trench, a second trench, and a third trench each formed inside the semiconductor substrate to reach a predetermined depth from the upper surface of the semiconductor substrate; a trench gate electrode formed inside the first trench through a first insulating film; a first trench emitter electrode formed inside the second trench through a second insulating film; a second trench emitter electrode formed inside the third trench through a third insulating film; a first hole barrier region of the first conductive type formed inside the semiconductor substrate between the first trench and the second trench; a first base region of a second conductive type opposite to the first conductive type formed inside the first hole barrier region; a first emitter region of the first conductive type formed inside the first base region; a second hole barrier region of the first conductive type formed inside the semiconductor substrate between the first trench and the third trench; a second base region of the second conductive type formed inside the second hole barrier region; a second emitter region of the first conductive type formed inside the second base region; a first floating region of the second conductive type formed inside the semiconductor substrate located on the other side surface side of both side surfaces of the second trench opposite to one side surface where the first hole barrier region is formed; and a second floating region of the second conductive type formed inside the semiconductor substrate located on the other side surface side of both side surfaces of the third trench opposite to one side surface where the second hole barrier region is formed. Each depth of the first floating region and the second floating region from the upper surface of the semiconductor substrate is shallower than each depth of the first trench, the second trench, and the third trench from the upper surface of the semiconductor substrate, and is deeper than each depth of the first base region and the second base region from the upper surface of the semiconductor substrate.

A method of manufacturing a semiconductor device according to one embodiment includes the steps of: (a) preparing a semiconductor substrate of a first conductive type having an upper surface and a lower surface opposite to the upper surface; (b) forming a first hole barrier region of the first conductive type and a second hole barrier region of the first conductive type inside the semiconductor substrate on the upper surface side of the semiconductor substrate; (c) after the step (b), forming a first trench and a second trench inside the semiconductor substrate so that the first hole barrier region is sandwiched therebetween in plan view, and forming a third trench inside the semiconductor substrate so that the second hole barrier region is sandwiched between the third trench itself and the first trench in plan view; (d) after the step (c), forming a first insulating film inside the first trench, a second insulating film inside the second trench, and a third insulating film inside the third trench; (e) after the step (d), forming a trench gate electrode inside the first trench through the first insulating film, a first trench emitter electrode inside the second trench through the second insulating film, and a second trench emitter electrode inside the third trench through the third insulating film; (f) after the step (e), forming a first base region of a second conductive type opposite to the first conductive type inside the first hole barrier region, forming a second base region of the second conductive type inside the second hole barrier region, forming a first floating region of the second conductive type inside the semiconductor substrate located on the other side surface side of both side surfaces of the second trench opposite to one side surface where the first hole barrier region is formed, and forming a second floating region of the second conductive type inside the semiconductor substrate located on the other side surface side of both side surfaces of the third trench opposite to one side surface where the second hole barrier region is formed; and (g) after the step (f), forming a first emitter region of the first conductive type inside the first base region, and forming a second emitter region of the first conductive type inside the second base region. Each depth of the first floating region and the second floating region from the upper surface of the semiconductor substrate is shallower than each depth of the first trench, the second trench, and the third trench from the upper surface of the semiconductor substrate, and is deeper than each depth of the first base region and the second base region from the upper surface of the semiconductor substrate.

A semiconductor device according to one embodiment includes an IGBT including a plurality of cells. Each of the plurality of cells includes a trench gate electrode, a first trench emitter electrode and a second trench emitter electrode formed in an n-type semiconductor substrate, a p-type first base region formed inside the semiconductor substrate located between the trench gate electrode and the first trench emitter electrode, and a p-type second base region formed inside the semiconductor substrate located between the trench gate electrode and the second trench emitter electrode. A p-type floating region is formed inside the semiconductor substrate located between the plurality of cells. A depth of the floating region is shallower than each depth of the trench gate electrode, the first trench emitter electrode and the second trench emitter electrode, and is deeper than each depth of the first base region and the second base region.

According to one embodiment, a semiconductor device having an IGBT with improved switching characteristics can be provided.

### BRIEF DESCRIPTION OF THE DRAWINGS

FIG. 1 is a plan view showing a semiconductor device in a first embodiment.

FIG. 2 is a plan view of a main portion showing the semiconductor device in the first embodiment.

FIG. 3 is a cross-sectional view showing the semiconductor device in the first embodiment.

FIG. 4 is a cross-sectional view showing the semiconductor device in the first embodiment.

FIG. 5 is a cross-sectional view of a main portion showing the semiconductor device in the first embodiment.

FIG. 6 is a graph showing an impurity concentration profile of active cells and inactive cells in the first embodiment.

FIG. 7 is a cross-sectional view of a main portion showing structures of the first embodiment, an examined example 1, and an examined example 2.

FIG. 8 is a graph showing performances of the first embodiment, the examined example 1, and the examined example 2.

FIG. 9 is a cross-sectional view showing a manufacturing process of the semiconductor device in the first embodiment.

FIG. 10 is a cross-sectional view showing the manufacturing process following FIG. 9.

FIG. 11 is a cross-sectional view showing the manufacturing process following FIG. 10.

FIG. 12 is a cross-sectional view showing the manufacturing process following FIG. 11.

FIG. 13 is a cross-sectional view showing the manufacturing process following FIG. 12.

FIG. 14 is a cross-sectional view showing the manufacturing process following FIG. 13.

FIG. 15 is a cross-sectional view showing the manufacturing process following FIG. 14.

FIG. 16 is a cross-sectional view showing the manufacturing process following FIG. 15.

FIG. 17 is a cross-sectional view showing the manufacturing process following FIG. 16.

FIG. 18 is a cross-sectional view showing the manufacturing process following FIG. 17.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Also, the X direction, Y direction, and Z direction described in this application intersect each other and are orthogonal to each other. In this application, the Z direction is described as the up and down direction, height direction, depth direction, or thickness direction of a certain structure. Also, expressions such as “plan view” or “planar view” used in this application mean that the surface constituted by the X direction and the Y direction is a “plane”, and this “plane” is viewed in the Z direction.

### First Embodiment

### <Structure of Semiconductor Device>

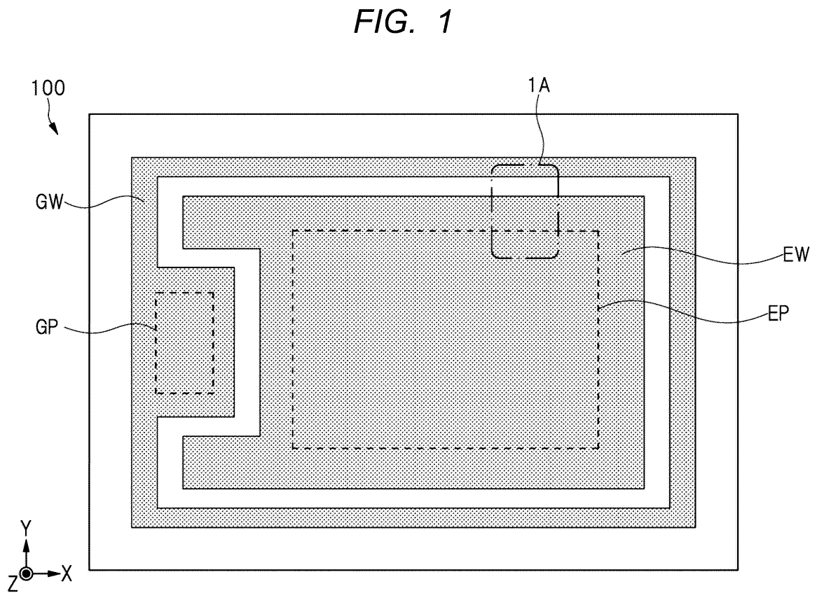

A structure of a semiconductor device 100 in a first embodiment will be described below using FIGS. 1 to 4.

FIG. 1 is a plan view showing a semiconductor chip, which is the semiconductor device 100. As shown in FIG. 1, most of the semiconductor device 100 is covered with an emitter wiring EW. A gate wiring GW surrounds the emitter wiring EW in plan view.

Although not shown in the drawings, the emitter wiring EW and the gate wiring GW are covered with a protective film such as a polyimide film. On the emitter wiring EW and the gate wiring GW, some of the protective film has openings, and regions exposed at the openings become an emitter pad EP and a gate pad GP. On the emitter pad EP and the gate pad GP, the semiconductor device 100 is electrically connected to other semiconductor chips, lead frames, wiring substrates or the like by connecting external connection members thereto. Note that the external connection member is, for example, a wire made of aluminum, gold, or copper, or a clip made of a copper plate.

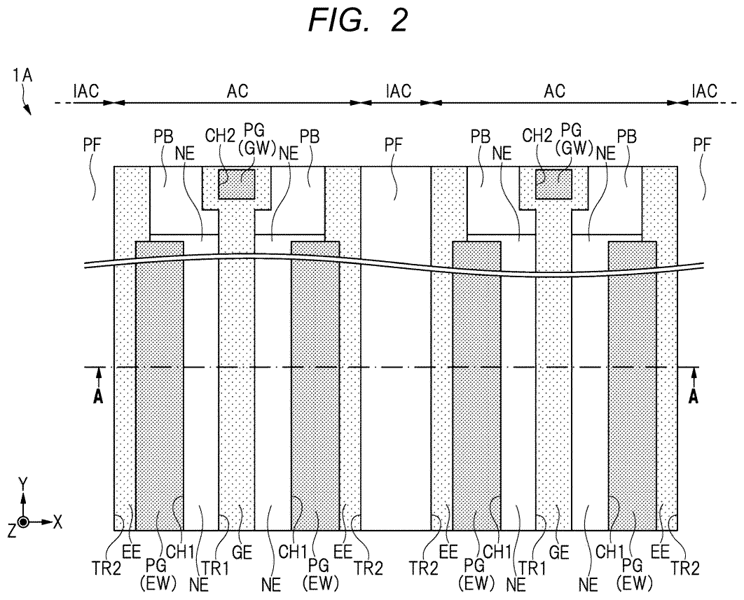

FIG. 2 is a plan view of a main portion corresponding to a region 1A shown in FIG. 1. The semiconductor device 100 includes an IGBT formed on a semiconductor substrate SUB. This IGBT is an EGE structure IGBT utilizing the IE effect. The EGE structure IGBT includes a plurality of active cells AC for performing the main operation of the IGBT and a plurality of inactive cells IAC provided between the active cells AC. One active cell AC includes one trench gate electrode GE and two trench emitter electrodes EE. The plurality of active cells AC are adjacent to each other in the X direction. In the semiconductor substrate SUB located between the active cells AC, a p-type floating region PF is provided.

As shown in FIG. 2, a plurality of trenches TR1, TR2 extend in the Y direction and are adjacent to each other in the X direction. The plurality of trenches TR1, TR2 are formed at the same pitch in the X direction. Inside the trench TR1, a trench gate electrode GE is formed through a gate insulating film GI. Inside the trench TR2, a trench emitter electrode EE is formed through a gate insulating film GI.

In the semiconductor substrate SUB of the active cell AC, a p-type base region PB is formed. In the base region PB, an n-type emitter region NE is formed. In the semiconductor substrate SUB of the inactive cell IAC, a floating region PF is formed. The emitter region NE extends intermittently in the Y direction while making contact with the trench TR1, but the emitter region NE is not formed near the end of the trench TR1 (near a hole CH2).

To the trench gate electrode GE, the gate wiring GW is electrically connected through a plug PG formed inside the hole CH2, and a gate potential is supplied during the operation of the IGBT. To the trench emitter electrode EE, the base region PB and the emitter region NE, the emitter wiring EW is electrically connected through the plug PG formed inside the hole CH1, and an emitter potential is supplied during the operation of the IGBT.

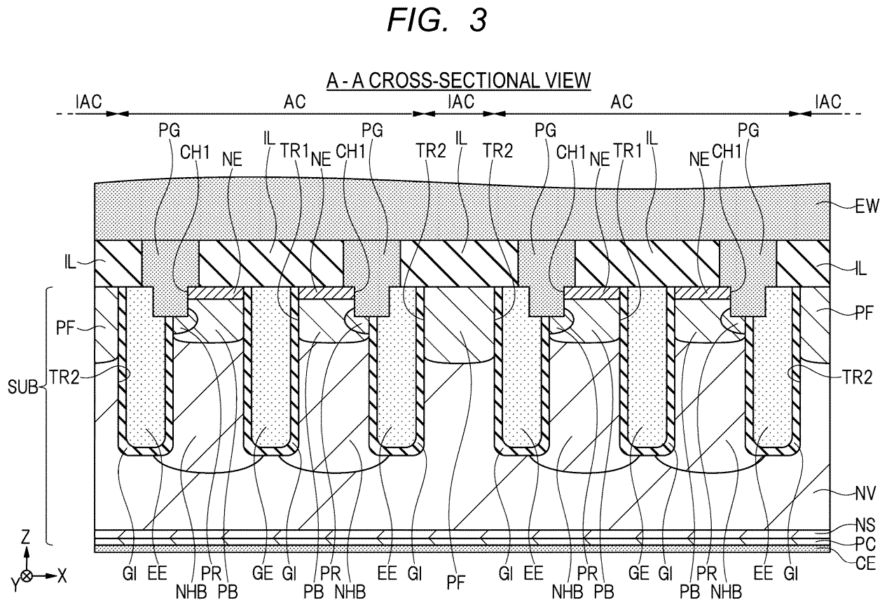

FIG. 3 is a cross-sectional view along line A-A shown in FIG. 2. The semiconductor device 100 includes an n-type semiconductor substrate SUB having an upper surface and a lower surface opposite to the upper surface. The semiconductor substrate SUB is made of n-type silicon and has a low concentration n-type drift region NV. Here, the n-type semiconductor substrate SUB itself constitutes the drift region NV. Note that the semiconductor substrate SUB may be a laminate film of an n-type silicon substrate and an n-type silicon layer grown by introducing phosphorus (P) by an epitaxial growth method on the silicon substrate. In that case, the n-type silicon layer having a lower impurity concentration than that of the n-type silicon substrate constitutes the drift region NV.

An n-type field stop region (impurity region) NS is formed on the lower surface of the semiconductor substrate SUB. The impurity concentration of the field stop region NS is higher than the impurity concentration of the drift region NV. The field stop region NS is provided to prevent the depletion layer extending from the p-n junction on the upper surface side of the semiconductor substrate SUB from reaching the p-type collector region PC during the turn-off of the IGBT.

A p-type collector region (impurity region) PC is formed on the lower surface of the semiconductor substrate SUB. The collector region PC is located below the field stop region NS.

A collector electrode CE is formed on the lower surface of the semiconductor substrate SUB. The collector electrode CE is electrically connected to the collector region PC and supplies the collector potential to the collector region PC. The collector electrode CE is a single-layer metal film such as an Au film, Ni film, Ti film, or AlSi film, or a laminated metal film appropriately laminated with these.

Note that the collector electrode CE, the collector region PC, and the field stop region NS are formed over the entire semiconductor substrate SUB of the active cell AC and the inactive cell IAC.

Inside the semiconductor substrate SUB of the active cell AC, the trenches TR1 and TR2 are formed to reach a predetermined depth from the upper surface of the semiconductor substrate SUB. The trenches TR1 and TR2 penetrate the emitter region NE, the base region PB, and the floating region PF to be described later. Each depth of the trenches TR1 and TR2 is, for example, 2 μm or more and 6 μm or less.

A gate insulating film (insulating film) GI is formed inside the trenches TR1 and TR2. A trench gate electrode GE is formed inside the trench TR1 through the gate insulating film GI. A trench emitter electrode EE is formed inside the trench TR2 through the gate insulating film (insulating film) GI. The gate insulating film GI is an insulating film such as a silicon oxide film. Each of the trench gate electrode GE and the trench emitter electrode EE is a conductive film such as a polycrystalline silicon film into which an n-type impurity has been introduced. A thickness of the gate insulating film GI is, for example, 70 nm or more and 150 nm or less.

In the active cell AC, an n-type hole barrier region (impurity region) NHB is formed inside the semiconductor substrate SUB between the trench TR1 and the trench TR2 (between the trench gate electrode GE and the trench emitter electrode EE). An impurity concentration of the hole barrier region NHB is higher than an impurity concentration of the drift region NV and lower than an impurity concentration of the emitter region NE. A depth of the hole barrier region NHB from the upper surface of the semiconductor substrate SUB is deeper than each depth of the trenches TR1 and TR2 from the upper surface of the semiconductor substrate SUB. The hole barrier region NHB suppresses the discharge of holes reaching the base region PB during the operation of the IGBT. That is, it functions as a barrier to holes.

Inside the hole barrier region NHB, a p-type base region (impurity region) PB is formed. Inside the p-type base region PB, an n-type emitter region (impurity region) NE is formed. An impurity concentration of the emitter region NE is higher than an impurity concentration of the drift region NV. A depth of the base region PB from the upper surface of the semiconductor substrate SUB is shallower than each depth of the trenches TR1, TR2 from the upper surface of the semiconductor substrate SUB. The base region PB, which is in contact with the trench TR1 and located below the emitter region NE, is used as a channel region.

One active cell AC of the IGBT includes one trench TR1, two trenches TR2, each gate insulating film GI in each trench TR1, TR2, one trench gate electrode GE, two trench emitter electrodes EE, two hole barrier regions NHB, two base regions PB, two emitter regions NE, and a collector region PC.

On the upper surface side of the semiconductor substrate SUB, the p-type floating region (impurity region) PF is formed inside the semiconductor substrate SUB between the active cells AC (inside the semiconductor substrate SUB of the inactive cell IAC). The floating region PF is not electrically connected to the gate wiring GW and the emitter wiring EW, no potential is supplied, and the floating region PF is in an electrically floating state.

On the upper surface of the semiconductor substrate SUB of the active cell AC and the inactive cell IAC, an interlayer insulating film IL is formed to cover the trenches TR1, TR2. The interlayer insulating film IL is, for example, a silicon oxide film. A thickness of the interlayer insulating film IL is, for example, 600 nm or more and 1500 nm or less.

A hole CH1 is formed inside the interlayer insulating film IL. The hole CH1 is formed to penetrate the interlayer insulating film IL to a depth deeper than the emitter region NE, and is formed so as not to penetrate the base region PB. In other words, the hole CH1 includes an opening formed in the interlayer insulating film IL and a recess formed inside the semiconductor substrate SUB to span between the trench emitter electrode EE and the emitter region NE. That is, the hole CH1 penetrates the interlayer insulating film IL and reaches the trench emitter electrode EE, the base region PB, and the emitter region NE. In other words, the hole CH1 is formed to overlap the trench emitter electrode EE, the base region PB, and the emitter region NE in plan view.

In the base region PB around the bottom of the hole CH1, a p-type high concentration diffusion region (impurity region) PR is formed. An impurity concentration of the high concentration diffusion region PR is higher than that of the base region PB. The high concentration diffusion region PR is mainly provided to reduce the contact resistance with the plug PG and to prevent latch-up.

The plug PG is embedded inside the hole CH1. The plug PG is in contact with the trench emitter electrode EE, the base region PB, the emitter region NE, and the high concentration diffusion region PP. The plug PG includes a barrier metal film and a conductive film formed on the barrier metal film. The barrier metal film is, for example, a laminate film of a titanium film and a titanium nitride film formed on the titanium film. The conductive film is, for example, a tungsten film.

At the upper part of the hole CH1, the interlayer insulating film IL recedes. That is, a size of the opening of the hole CH1 upper than the upper surface of the semiconductor substrate SUB is larger than a size of the opening of the hole CH1 lower than the upper surface of the semiconductor substrate SUB. Therefore, a part of the upper surface of each of the emitter region NE and the trench emitter electrode EE is exposed from the interlayer insulating film IL. Therefore, inside the hole CH1, the plug PG makes contact with not only the side surface of each of the emitter region NE and the trench emitter electrode EE, but also a part of the upper surface of each of the emitter region NE and the trench emitter electrode EE. This allows the reduction of the contact resistance between the plug PG and the emitter region NE and the trench emitter electrode EE.

Although not shown here, a hole CH2 as shown in FIG. 2 is also formed in the interlayer insulating film IL. The hole CH2 is formed to overlap the trench gate electrode GE in plan view, penetrates the interlayer insulating film IL, and reaches the trench gate electrode GE. Inside the hole CH2, the plug PG is also formed. Also, at the upper part of the hole CH2, the interlayer insulating film IL recedes. That is, a size of the opening of the hole CH2 upper than the upper surface of the semiconductor substrate SUB is larger than a size of the opening of the hole CH2 lower than the upper surface of the semiconductor substrate SUB.

Inside the interlayer insulating film IL located on the floating region PF, holes such as CH1 and CH2 are not formed.

On the interlayer insulating film IL, the emitter wiring EW is formed. The emitter wiring EW is electrically connected to the trench emitter electrode EE, the base region PB, the emitter region NE, and the high concentration diffusion region PR through the plug PG inside the hole CH1, and supplies an emitter potential to these members. Although not shown here, on the interlayer insulating film IL, the gate wiring GW, which is formed by the same manufacturing process as that of the emitter wiring EW, is also formed. The gate wiring GW is electrically connected to the trench gate electrode GE through the plug PG inside the hole CH2, and supplies a gate potential to the trench gate electrode GE.

Such emitter wiring EW and gate wiring GW include a barrier metal film and a conductive film formed on the barrier metal film. The barrier metal film is, for example, a TiW film. The conductive film is, for example, an aluminum alloy film to which copper or silicon has been added. The aluminum alloy film is the main conductor film of the emitter wiring EW and the gate wiring GW, and is sufficiently thicker than the TiW film.

### <Details of the Impurity Regions Around the Trench>

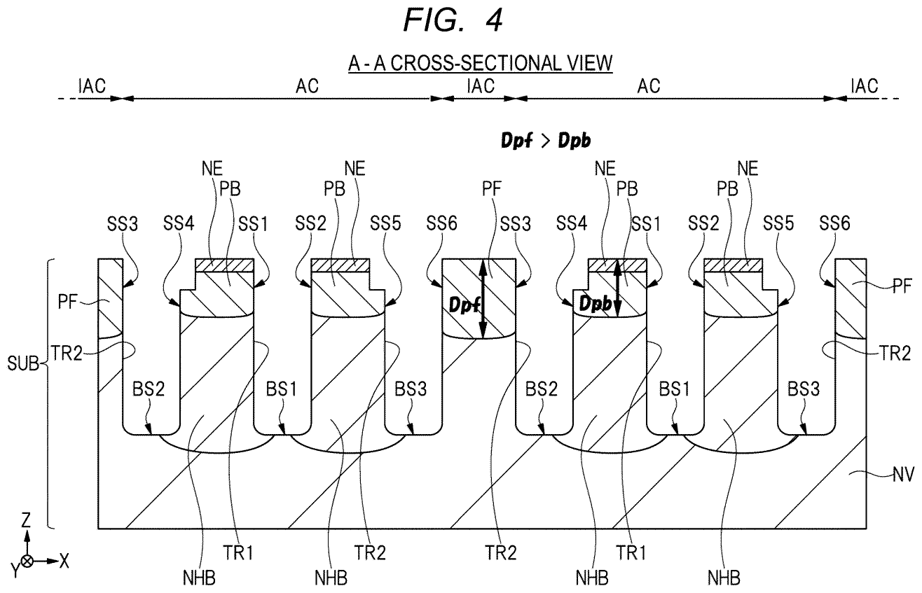

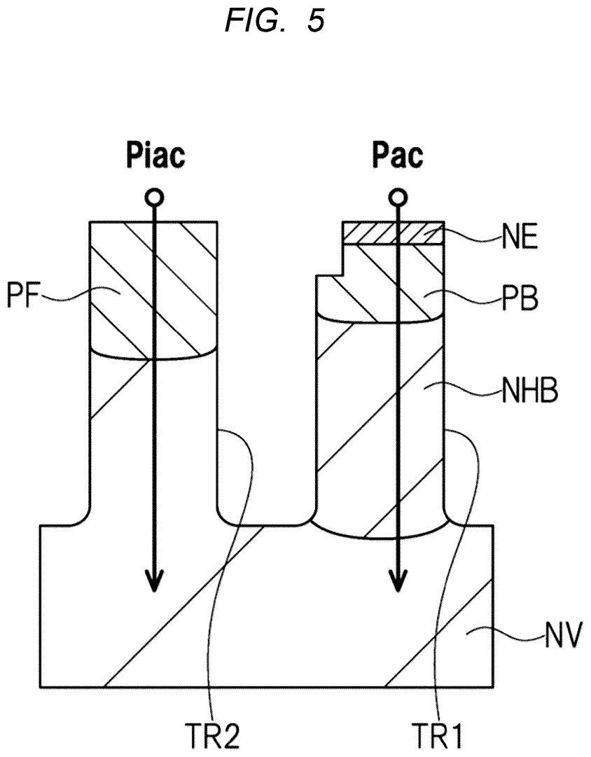

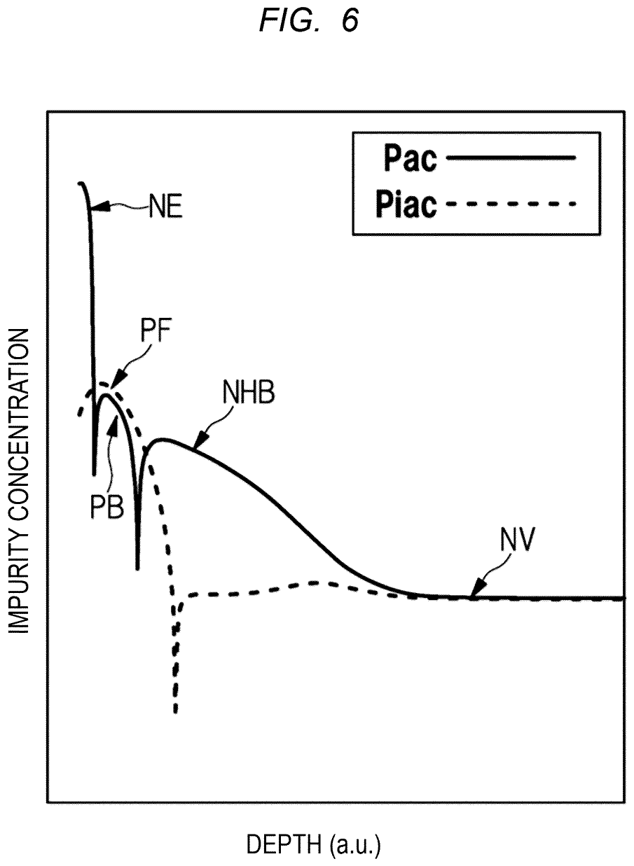

FIG. 4 shows only the trench TR1, trench TR2, and the main impurity regions around them, in the cross-sectional structure of FIG. 3. FIG. 5 shows a cross-sectional direction of an impurity concentration profile Pac of the active cell AC and an impurity concentration profile Piac of the inactive cell IAC. FIG. 6 is a graph showing the impurity concentration profiles Pac and Piac shown in FIG. 5.

Using FIGS. 4 to 6, the detailed relationship among one trench TR1 included in one active cell AC, two trenches TR2, and the impurity regions around them will be described.

As shown in FIG. 4, the trench TR1 has a side surface SS1, a side surface SS2 opposing the side surface SS1, and a bottom surface BS1 connecting the side surfaces SS1 and SS2. One of the trenches TR2 has a side surface SS3, a side surface SS4 opposing the side surface SS3, and a bottom surface BS2 connecting the side surfaces SS3 and SS4. The other trench TR2 has a side surface SS5, a side surface SS6 opposing the side surface SS5, and a bottom surface BS3 connecting the side surfaces SS5 and SS6.

The trench TR1 and one of the trenches TR2 are provided at an interval so that the side surfaces SS1 and SS4 are adjacent. The trench TR1 and the other trench TR2 are provided at an interval so that the side surfaces SS2 and SS5 are adjacent.

One hole barrier region NHB, one base region PB, and one emitter region NE are provided in the semiconductor substrate SUB between the side surfaces SS1 and SS4. One hole barrier region NHB makes contact with the side surfaces SS1, SS4, the bottom surface BS1, and the bottom surface BS2, but does not make contact with the side surface SS3. One base region PB makes contact with the side surfaces SS1 and SS4, but does not make contact with the bottom surfaces BS1 and BS2. One emitter region NE makes contact with the side surface SS1.

The other hole barrier region NHB, the other base region PB, and the other emitter region NE are provided in the semiconductor substrate SUB between the side surfaces SS2 and SS5. The other hole barrier region NHB makes contact with the side surfaces SS2 and SS5 and the bottom surfaces BS1 and BS3, but does not make contact with the side surface SS6. The other base region PB makes contact with the side surfaces SS2 and SS5, but does not make contact with the bottom surfaces BS1 and BS3. The other emitter region NE makes contact with the side surface SS2.

Each floating region PF is provided in the semiconductor substrate SUB between the side surfaces SS3 and SS6, makes contact with the side surfaces SS3 and SS6, but does not make contact with the bottom surfaces BS2 and BS3.

As shown in FIG. 4, a depth Dpb of the base region PB from the upper surface of the semiconductor substrate SUB and a depth Dpf of the floating region PF from the upper surface of the semiconductor substrate SUB are shallower than each depth of the trenches TR1 and TR2 from the upper surface of the semiconductor substrate SUB.

As can be seen from the impurity concentration profile in FIG. 6, the floating region PF is formed to a deeper position than the base region PB. That is, the depth Dpf of the floating region PF is deeper than the depth Dpb of the base region PB. Also, the impurity concentration of the floating region PF is effectively higher than the impurity concentration of the base region PB.

Inside the semiconductor substrate SUB of the active cell AC, the hole barrier region NHB is formed. However, inside the semiconductor substrate SUB of the inactive cell IAC, a high concentration n-type impurity region such as the hole barrier region NHB, which is higher in concentration than the semiconductor substrate SUB (drift region NV), is not formed. In other words, in the active cell AC, the base region PB forms a p-n junction with the hole barrier region NHB and the emitter region NE. Also, in the inactive cell IAC, the floating region PF forms a p-n junction with the semiconductor substrate SUB (drift region NV).

Since the p-type base region PB is formed inside the high concentration n-type hole barrier region NHB, which is higher in concentration than the semiconductor substrate SUB, the proportion of p-type conductivity being cancelled by n-type conductivity is greater in the base region PB than in the floating region PF. Therefore, the impurity concentration of the base region PB formed inside the hole barrier region NHB is effectively lower than the impurity concentration of the floating region PF. Also, the depth Dpb of the base region PB is shallower than the depth Dpf of the floating region PF.

### <Examined Example and Main Features of the First Embodiment>

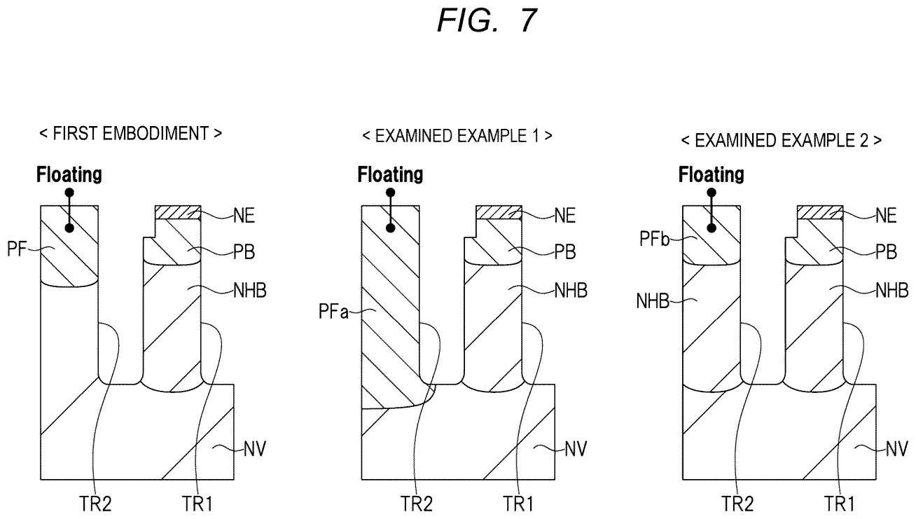

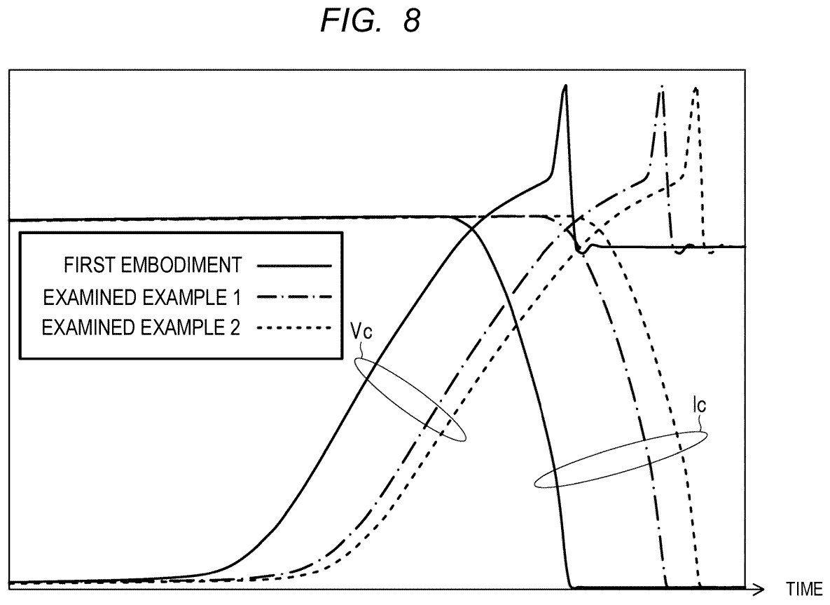

The main features of the semiconductor device 100 of the first embodiment will be described below, using FIGS. 7 and 8, in comparison with the examined examples 1 and 2 of the semiconductor devices as necessary. Note that the semiconductor devices of the examined examples 1 and 2 are based on the technology disclosed in Patent Document 1 or 2, and were examined by the present inventors. FIG. 8 is a graph showing turn-off waveforms of the first embodiment, the examined example 1 and the examined example 2.

The examined example 1 is with reference to the GGEE structure technology as described in Patent Document 1 or the like. As shown in FIG. 7, inside the semiconductor substrate SUB of the inactive cell IAC, a p-type impurity region PFa is formed instead of the floating region PF of the first embodiment. The impurity region PFa is in an electrically floating state. The impurity region PFa is formed deeper than the floating region PF and is formed to cover the bottom surface (BS2, BS3) of the trench TR2.

The examined example 2 is one in which the impurity structure of the inactive cell IAC is made the same as the impurity structure of the active cell AC, except that the emitter region NE is absent. As shown in FIG. 7, the n-type hole barrier region NHB is formed inside the semiconductor substrate SUB of the inactive cell IAC, and a p-type impurity region PFb is formed inside the hole barrier region NHB. The impurity region PFb is formed by the same manufacturing process as that of the base region PB, but the impurity region PFb is in an electrically floating state.

In IGBTs for PFC applications, the priority for securing load short-circuit tolerance is low, and therefore, a saturation current density can be increased. Therefore, it is necessary to increase the MOSFET component per unit area of the IGBT. In the GGEE structure, the MOSFET component is formed on one side surface of each of the two trench gate electrodes GE. In the EGE structure of the first embodiment, the MOSFET component can be formed on both side surfaces of one trench gate electrode GE. Therefore, the MOSFET component per unit area of the IGBT can be increased.

Also, in the GGEE structure, the distance between the trench gate electrode GE and the trench emitter electrode EE is relatively long. However, in the first embodiment, the plurality of trenches TR1, TR2 are formed at the same pitch. In this respect as well, the MOSFET component per unit area of the IGBT can be further increased.

Also, since the connections among the trench emitter electrode EE, the base region PB, the emitter region NE and the emitter wiring EW are made common in one hole CH1 (one plug PG), the miniaturization of the IGBT can be achieved. This allows the MOSFET component per unit area of the IGBT to be further increased.

Also, as shown in FIG. 2, the emitter region NE extends intermittently in the Y direction while making contact with the trench TR1. This widens the gate width of the MOSFET component, and allows the saturation current density to be further increased.

However, by increase in the MOSFET component, the parasitic capacitance between the trench gate electrode GE and the drift region NV is increased, the switching speed is decreased, and the switching loss is increased. Therefore, the floating region PF is provided between the trench emitter electrodes EE to accumulate holes to be injected from the bottom surface of the semiconductor substrate SUB.

Here, a parasitic PMOS is configured to include the floating region PF as the source, the base region PB as the drain, the drift region NV and the hole barrier region NHB as the channel, and the trench emitter electrode EE, which is at the emitter potential, as the gate. When enough holes are accumulated in the floating region PF and the potential becomes high, the parasitic PMOS turns on. Then, the holes move from the floating region PF to the base region PB and are automatically discharged to the emitter wiring EW. Therefore, the decrease in switching speed and the increase in switching loss can be suppressed. Also, due to the above function of the parasitic PMOS, the potential fluctuation of the floating region PF is suppressed, and therefore, the potential of the trench gate electrode GE can be stabilized, and the switching loss during switching can be suppressed.

As shown in FIG. 7, in the examined example 1, instead of the floating region PF, a relatively deep impurity region PFa is formed. In this case, holes accumulate in the impurity region PFa, and the depletion layer cannot spread between the trench emitter electrode EE and the trench gate electrode GE until all the holes in the impurity region PFa are discharged. Therefore, as shown in FIG. 8, in the examined example 1, the rise of the collector voltage Vc is slower, and the timing of the flow of the collector current Ic is later than those of the first embodiment. That is, in the examined example 1, the turn-off is delayed, and the switching speed is reduced.

Also, as described in the GGEE structure, when the distance between the trench emitter electrode EE and the trench gate electrode GE is relatively large, a deep p-type impurity region such as the impurity region PFa is required because the breakdown voltage BVCES (the withstand voltage between the collector region PC and the emitter region NE) decreases. However, as described in the first embodiment, where a plurality of trenches TR1, TR2 are formed at the same pitch, the trench emitter electrodes EE at the emitter potential are evenly arranged, and therefore, there is no need to worry about a decrease in the breakdown voltage BVCES. Therefore, the depth of the floating region PF in the first embodiment may be shallower than the depth of the trench TR2.

Note that the distance between two trenches TR2 (trench emitter electrodes EE) adjacent to each other across the floating region PF may be narrower than the distance between the trench TR1 (trench gate electrode GE) and the trench TR2 (trench emitter electrode EE). This allows the proportion of MOSFET components inside the semiconductor device 100 to increase. Therefore, it may be possible to achieve a reduction in on-voltage or an improvement in switching characteristics.

As shown in FIG. 7, in the examined example 2, the hole barrier region NHB is formed under the p-type impurity region PFb. In this case, holes injected from the bottom surface of the semiconductor substrate SUB are inhibited by the hole barrier region NHB, and as shown in FIG. 8, in the examined example 2, the rise of the collector voltage Vc is slower, and the timing of the flow of the collector current Ic is later than those of the first embodiment. That is, in the examined example 2, the turn-off is delayed, and the switching speed is reduced.

As described above, in the first embodiment, by applying the EGE type IGBT to the active cell AC and providing the floating region PF in the inactive cell IAC, it is possible to maintain a low on-voltage while achieving the high switching speed and the reduction in switching loss. In other words, according to the first embodiment, the semiconductor device 100 equipped with the IGBT with the improved switching characteristics can be provided.

### <Method of Manufacturing Semiconductor Device>

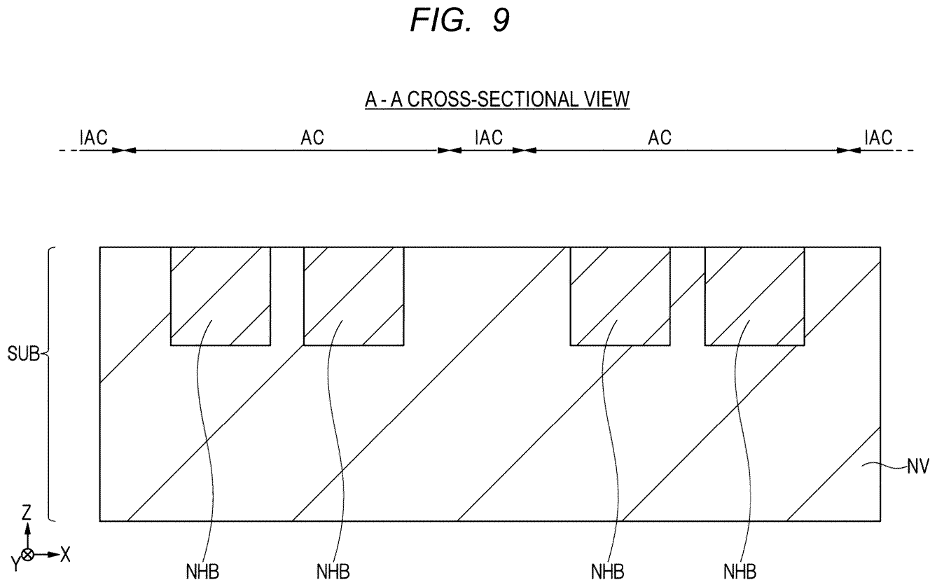

Hereinafter, each manufacturing process included in the method of manufacturing the semiconductor device 100 in the first embodiment will be described using FIGS. 9 to 18.

As shown in FIG. 9, first, an n-type semiconductor substrate SUB having an upper surface and a lower surface is prepared. The semiconductor substrate SUB is made of silicon. As mentioned above, the semiconductor substrate SUB may be a laminate body of an n-type silicon substrate and an n-type silicon layer grown by introducing phosphorus (P) onto the silicon substrate by an epitaxial growth method.

Next, by using photolithography technology and ion implantation method, the hole barrier region NHB is selectively formed inside the semiconductor substrate SUB on the upper surface side of the semiconductor substrate SUB.

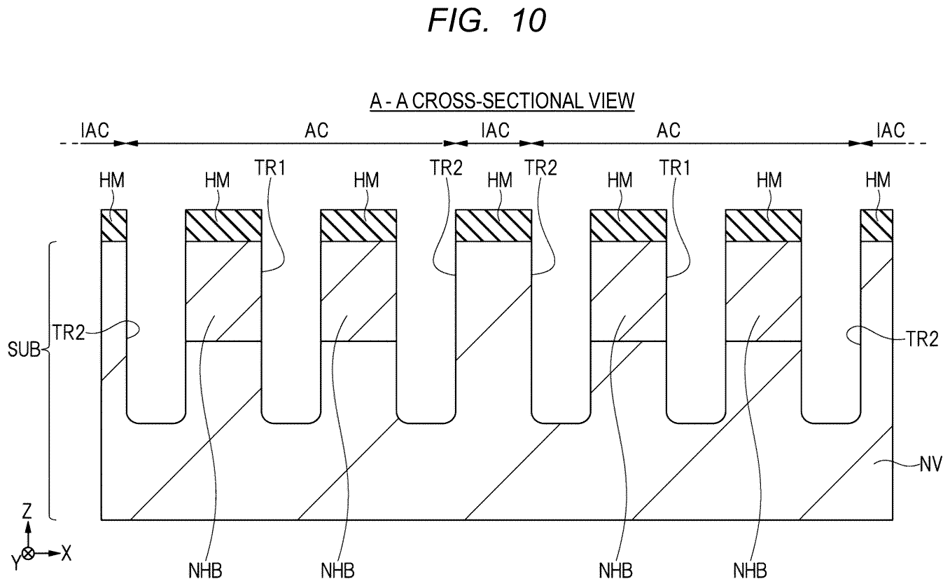

As shown in FIG. 10, trenches TR1 and TR2 are formed inside the semiconductor substrate SUB so that the hole barrier region NHB is located between the trench TR1 and the trench TP2 on the upper surface side of the semiconductor substrate SUB. In other words, trenches TR1 and TR2 are formed inside the semiconductor substrate SUB so as to sandwich the hole barrier region NHB in plan view.

First, for example, an oxide silicon film is formed on the upper surface of the semiconductor substrate SUB by, for example, a CVD method. Next, a resist pattern with an opening is formed on the silicon oxide film. Then, by performing anisotropic etching using the resist pattern as a mask, the silicon oxide film is patterned to form a hard mask HM. Then, the resist pattern is removed by ashing.

Next, by performing anisotropic etching using the hard mask HM as a mask, trenches TR1 and TR2 reaching a predetermined depth from the upper surface of the semiconductor substrate SUB are formed inside the semiconductor substrate SUB. Then, the hard mask HM is removed by, for example, wet etching using a solution containing hydrofluoric acid.

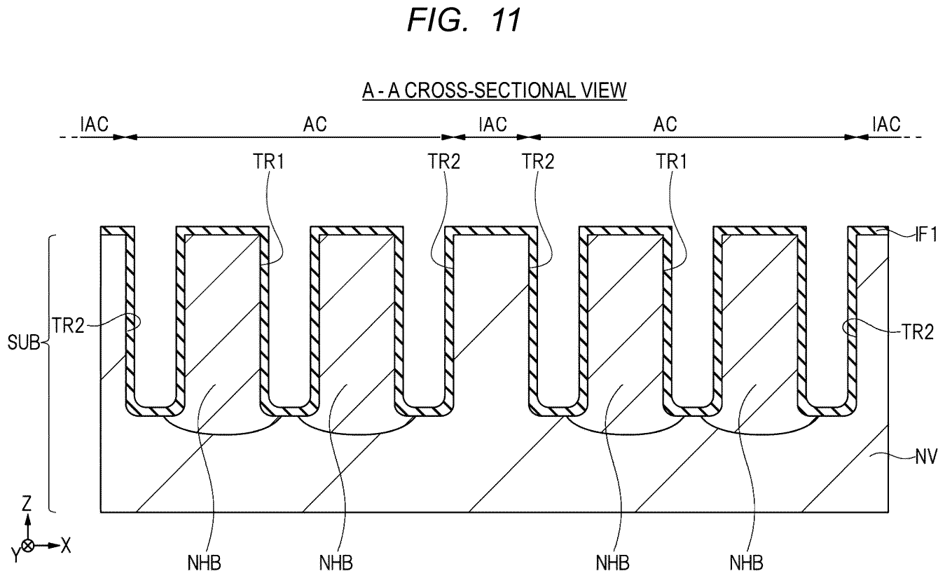

As shown in FIG. 11, a sacrificial oxide film IF1 is formed inside trench TR1, inside trench TR2, and on the upper surface of the semiconductor substrate SUB. This removes the damage layer formed inside the semiconductor substrate SUB. Then, the sacrificial oxide film IF1 is removed by, for example, isotropic etching using a solution containing hydrofluoric acid.

Note that the sacrificial oxide film IF1 is formed by heat-treating the semiconductor substrate SUB. This heat treatment is performed in an atmosphere filled with oxygen gas under conditions of, for example, 1100° C., for 30 minutes or longer and 60 minutes or shorter.

By this heat treatment, impurities contained in the hole barrier region NHB are diffused. The depth of the hole barrier region NHB from the upper surface of the semiconductor substrate SUB becomes deeper than each depth of the trench TR1 and trench TR2 from the upper surface of the semiconductor substrate SUB.

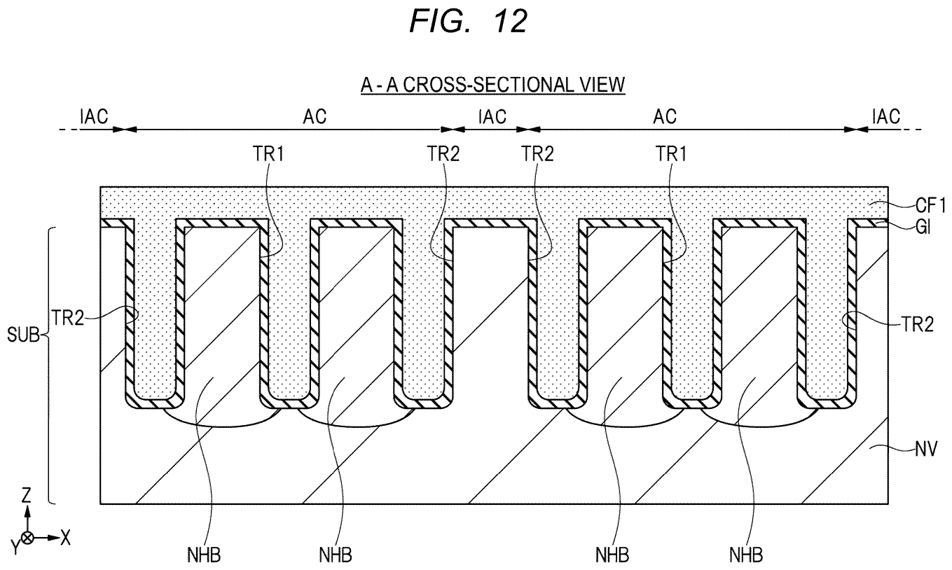

As shown in FIG. 12, a gate insulating film (insulating film) GI and a conductive film CF1 are formed inside trenches TR1 and TR2.

First, a gate insulating film GI is formed inside trenches TR1 and TR2 and on the upper surface of the semiconductor substrate SUB by heat treatment using oxygen gas and hydrogen gas under conditions of, for example, 950° C. for 60 minutes.

Next, a conductive film CF1 is formed on the gate insulating film GI by, for example, a CVD method so as to fill the inside of trenches TR1 and TR2 through the gate insulating film GI. The conductive film CF1 is, for example, a polycrystalline silicon film into which n-type impurities have been introduced.

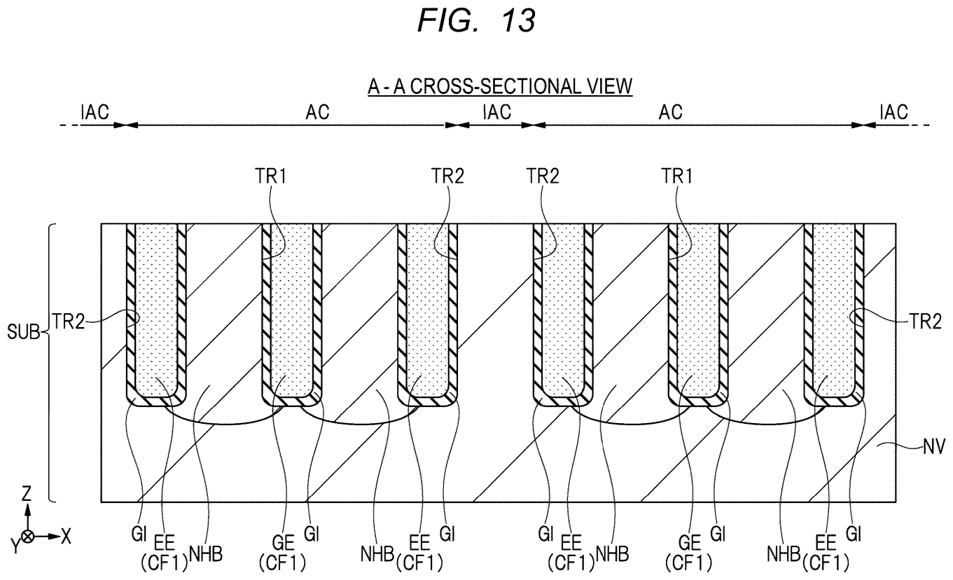

As shown in FIG. 13, the trench gate electrode GE is formed inside the trench TR1 through the gate insulating film GI, and the trench emitter electrode EE is formed inside the trench TR2 through the gate insulating film GI.

First, the conductive film CF1 formed outside trenches TR1 and TR2 is removed by anisotropic etching. The conductive film CF1, which was formed inside the trench TR1, is left as the trench gate electrode GE, and the conductive film CF1, which was formed inside the trench TR2, is left as the trench emitter electrode EE. Next, the gate insulating film GI, which was formed outside the trenches TR1 and TR2, is removed by an isotropic etching, an anisotropic etching or an etching process in combination of these.

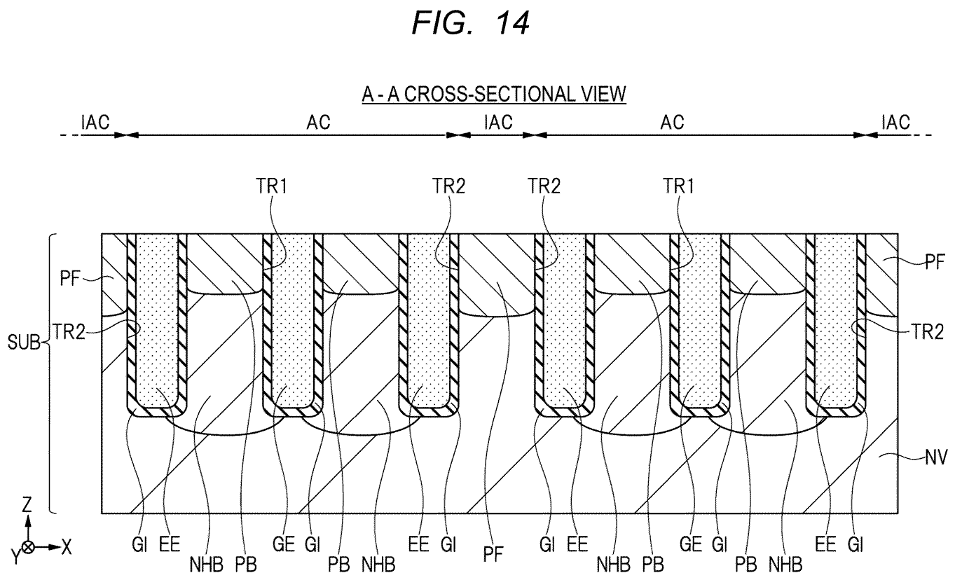

As shown in FIG. 14, the p-type base region PB is formed inside the hole barrier region NHB by ion implantation. At the same time, the p-type floating region PF is formed inside the semiconductor substrate SUB, which is located on the other side surface of both side surfaces of the trench TR2 opposite to one side surface where the hole barrier region NHB is formed. Note that the p-type base region PB and the floating region PF may be formed by a plurality of ion implantations. By appropriately adjusting the injection energy each time, the floating region PF of the desired depth can be formed.

That is, referring to FIG. 4, the base region PB is formed inside the semiconductor substrate SUB located between the side surfaces SS1 and SS4 and between the side surfaces SS2 and SS5, and the floating region PF is formed inside the semiconductor substrate SUB located between the side surfaces SS3 and SS6. In other words, the base region PB is formed inside the semiconductor substrate SUB of the active cell AC, and the floating region PF is formed inside the semiconductor substrate SUB of the inactive cell IAC.

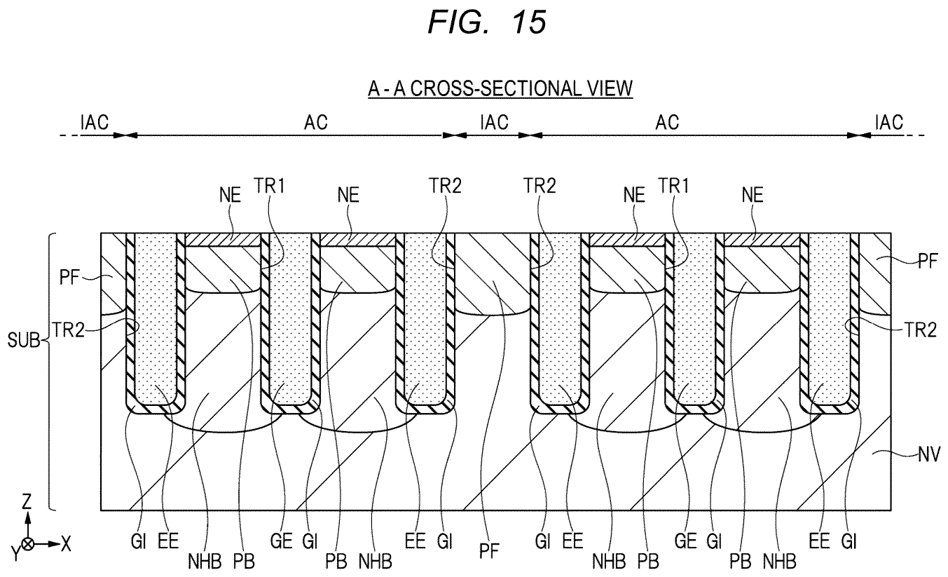

As shown in FIG. 15, the n-type emitter region NE is selectively formed inside the base region PB by the photolithography technology and the ion implantation method. Then, a heat treatment is performed to activate the impurities contained in the hole barrier region NHB, the floating region PF, the base region PB, and the emitter region NE. This heat treatment is performed in, for example, an atmosphere filled with an inert gas such as nitrogen gas under conditions of 900° C. or higher and 1000° C. or lower, and 30 seconds or longer and 50 seconds or shorter.

At this point, the impurity concentration profile shown in FIG. 6 is formed. Inside the semiconductor substrate SUB where the base region PB is formed, the hole barrier region NHB is formed. However, inside the semiconductor substrate SUB where the floating region PF is formed, there is no n-type impurity region with a higher concentration such as the hole barrier region NHB than that of the semiconductor substrate SUB (drift region NV). Therefore, the proportion of the p-type conductivity being cancelled by the n-type conductivity is higher in the base region PB than in the floating region PF. Therefore, although the base region PB and the floating region PF are formed in the same ion implantation process, the impurity concentration of the base region PB is effectively lower than that of the floating region PF. Also, the depth Dpb of the base region PB is shallower than the depth Dpf of the floating region PF.

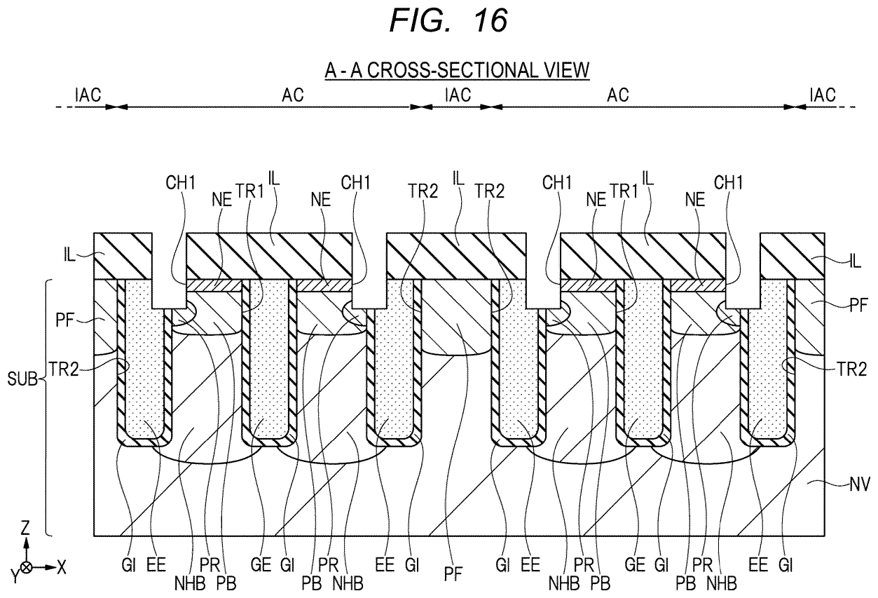

As shown in FIG. 16, first, the interlayer insulating film IL is formed on the upper surface of the semiconductor substrate SUB so as to cover the trenches TR1 and TR2 by, for example, a CVD method. The interlayer insulating film IL is, for example, a silicon oxide film.

Next, the hole CH1 is formed inside the interlayer insulating film IL by photolithography technology and anisotropic etching process. The hole CH1 reaches the trench emitter electrode EE, the base region PB, and the emitter region NE. Next, the p-type high concentration diffusion region PR is selectively formed inside the base region PB located at the bottom of the hole CH1 by ion implantation.

Next, although not shown here, the hole CH2 reaching the trench gate electrode GE is formed inside the interlayer insulating film IL by photolithography technology and anisotropic etching process. The process of forming the hole CH1 and the process of forming the hole CH2 may be performed in any order.

Not only during the process of forming holes CH1 and CH2, but also in subsequent manufacturing processes, no hole is formed inside the interlayer insulating film IL located on the floating region PF. Therefore, the floating region PF becomes a region where no potential is supplied, and is electrically in the floating state.

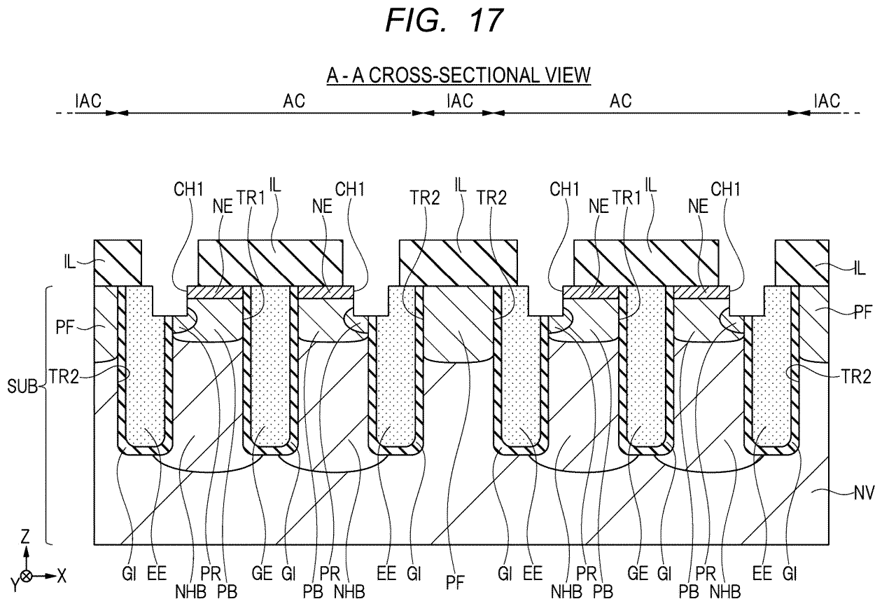

As shown in FIG. 17, by performing an isotropic etching process on the interlayer insulating film IL, the interlayer insulating film IL is receded. As a result, the opening width of the hole CH1 located on the upper surface of the semiconductor substrate SUB becomes larger than the opening width of the hole CH1 located inside the semiconductor substrate SUB. Note that the interlayer insulating film IL of the hole CH2 is also receded by this isotropic etching process.

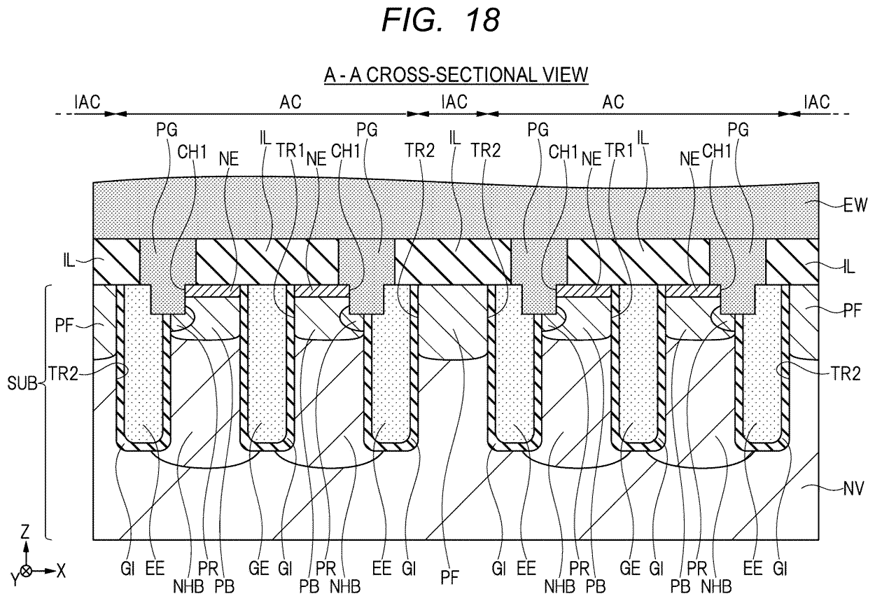

As shown in FIG. 18, the plug PG is formed inside the hole CH1, and the emitter wiring EW is formed on the interlayer insulating film IL.

First, the barrier metal film is formed inside the hole CH1 and on the interlayer insulating film IL. The barrier metal film can be formed by forming a titanium film inside the hole CH1 and on the interlayer insulating film IL by, for example, a sputtering method, and forming a titanium nitride film on the titanium film by, for example, a sputtering method. Next, a conductive film made of, for example, a tungsten film is formed on the barrier metal film by, for example, a CVD method so as to fill the inside of the hole CH1. Then, the conductive film and the barrier metal film formed outside the hole CH1 are removed by an anisotropic etching process. As a result, the plug PG is formed so as to fill the inside of the hole CH1. Note that the plug PG is also formed inside the hole CH2 during these manufacturing processes.

Next, the emitter wiring EW is formed on the interlayer insulating film IL. First, a TiW film is formed on the interlayer insulating film IL by, for example, a sputtering method, and an aluminum alloy film is formed on the TiW film by, for example, a sputtering method. Then, the emitter wiring EW is formed by patterning the TiW film and the aluminum alloy film by photolithography technology and dry etching process. Note that the gate wiring GW is also formed on the interlayer insulating film IL during these manufacturing processes.

Afterwards, the structure shown in FIG. 3 is obtained through the following manufacturing processes. First, the wafer is ground to be extremely thin as necessary. Then, by performing ion implantation from the lower surface of the semiconductor substrate SUB, the n-type field stop region NS and the p-type collector region PC are formed inside the semiconductor substrate SUB. After these ion implantations, impurities contained in the field stop region NS and the collector region PC are activated by laser annealing. Then, a metal film such as an Au film, Ni film, Ti film or AlSi film is formed on the lower surface of the semiconductor substrate SUB by, for example, a sputtering method. This metal film becomes the collector electrode CE. The collector electrode CE may be a laminated film formed by appropriately laminating the metal film.

Thus, according to the manufacturing method of the first embodiment, the semiconductor device 100 can be manufactured using the same manufacturing processes as those of manufacturing the IGBT with the GGEE structure and the EGE structure as described in Patent Document 1. Therefore, the development period can be shortened, new manufacturing equipment is not required, and manufacturing costs can be reduced.

Furthermore, according to the manufacturing method of the first embodiment, the floating region PF can be formed in the process of forming the base region PB. Therefore, it is possible to omit the formation of the deep floating region shown in Patent Document 1, etc., and to reduce the manufacturing cost accordingly.

Although the present invention has been specifically described based on the embodiments, the present invention is not limited to these embodiments and can be variously modified without departing from the spirit thereof.

What is claimed is:

1. A semiconductor device comprising:
a semiconductor substrate of a first conductive type having an upper surface and a lower surface opposite to the upper surface;
a first trench, a second trench, and a third trench each formed inside the semiconductor substrate to reach a predetermined depth from the upper surface of the semiconductor substrate;
a trench gate electrode formed inside the first trench through a first insulating film;
a first trench emitter electrode formed inside the second trench through a second insulating film;
a second trench emitter electrode formed inside the third trench through a third insulating film;
a first hole barrier region of the first conductive type formed inside the semiconductor substrate between the first trench and the second trench;
a first base region of a second conductive type opposite to the first conductive type formed inside the first hole barrier region;
a first emitter region of the first conductive type formed inside the first base region;
a second hole barrier region of the first conductive type formed inside the semiconductor substrate between the first trench and the third trench;
a second base region of the second conductive type formed inside the second hole barrier region;
a second emitter region of the first conductive type formed inside the second base region;
a first floating region of the second conductive type formed inside the semiconductor substrate located on the other side surface side of both side surfaces of the second trench opposite to one side surface where the first hole barrier region is formed; and
a second floating region of the second conductive type formed inside the semiconductor substrate located on the other side surface side of both side surfaces of the third trench opposite to one side surface where the second hole barrier region is formed,
wherein each depth of the first floating region and the second floating region from the upper surface of the semiconductor substrate is shallower than each depth of the first trench, the second trench, and the third trench from the upper surface of the semiconductor substrate, and is deeper than each depth of the first base region and the second base region from the upper surface of the semiconductor substrate.

2. The semiconductor device according to claim 1,
wherein each impurity concentration of the first floating region and the second floating region is higher than each impurity concentration of the first base region and the second base region.

3. The semiconductor device according to claim 1,
wherein each depth of the first hole barrier region and the second hole barrier region from the upper surface of the semiconductor substrate is deeper than each depth of the first trench, the second trench, and the third trench from the upper surface of the semiconductor substrate.

4. The semiconductor device according to claim 1, further comprising:
an interlayer insulating film formed on the upper surface of the semiconductor substrate so as to cover the first trench, the second trench, and the third trench;
a first hole penetrating the interlayer insulating film and reaching the first trench emitter electrode, the first base region, and the first emitter region;
a second hole penetrating the interlayer insulating film and reaching the second trench emitter electrode, the second base region, and the second emitter region;
a third hole penetrating the interlayer insulating film and reaching the trench gate electrode;
a first plug formed inside the first hole;
a second plug formed inside the second hole;
a third plug formed inside the third hole; and
an emitter wiring and a gate wiring formed on the interlayer insulating film,
wherein the first trench emitter electrode, the first base region, and the first emitter region are electrically connected to the emitter wiring through the first plug,
wherein the second trench emitter electrode, the second base region, and the second emitter region are electrically connected to the emitter wiring through the second plug,
wherein the trench gate electrode is electrically connected to the gate wiring through the third plug, and
wherein each of the first floating region and the second floating region is in an electrically floating state.

5. The semiconductor device according to claim 4,
wherein no hole is formed inside the interlayer insulating film located on the first floating region and the second floating region.

6. The semiconductor device according to claim 1,
wherein the first trench, the second trench, and the third trench extend in a first direction in plan view, and are adjacent to each other in a second direction orthogonal to the first direction, and
wherein the first emitter region and the second emitter region intermittently extend in the first direction while making contact with the first trench.

7. The semiconductor device according to claim 6, further comprising:
a collector region of the second conductive type formed on the lower surface of the semiconductor substrate,
wherein an active cell of an IGBT includes the trench gate electrode, the first trench emitter electrode, the second trench emitter electrode, the first hole barrier region, the second hole barrier region, the first base region, the second base region, the first emitter region, the second emitter region, and the collector region.

8. The semiconductor device according to claim 7, further comprising:
a plurality of the active cells,
wherein the plurality of the active cells are adjacent to each other in the second direction, and
wherein the first floating region or the second floating region is formed inside the semiconductor substrate located between the plurality of the active cells.

9. The semiconductor device according to claim 8,
wherein the first trench, the second trench, and the third trench included in each of the plurality of the active cells are formed at the same pitch in the second direction.

10. The semiconductor device according to claim 1,
wherein each of the first floating region and the second floating region forms a p-n junction with the semiconductor substrate.

11. The semiconductor device according to claim 1,
wherein the other side surface of the second trench does not make contact with the first hole barrier region, and
wherein the other side surface of the third trench does not make contact with the second hole barrier region.

12. A method of manufacturing a semiconductor device comprising steps of:
(a) preparing a semiconductor substrate of a first conductive type having an upper surface and a lower surface opposite to the upper surface;
(b) forming a first hole barrier region of the first conductive type and a second hole barrier region of the first conductive type on the upper surface of the semiconductor substrate;
(c) after the step (b), forming a first trench and a second trench inside the semiconductor substrate so that the first hole barrier region is sandwiched therebetween in plan view, and forming a third trench inside the semiconductor substrate so that the second hole barrier region is sandwiched between the third trench itself and the first trench in plan view;
(d) after the step (c), forming a first insulating film inside the first trench, a second insulating film inside the second trench, and a third insulating film inside the third trench;
(e) after the step (d), forming a trench gate electrode inside the first trench through the first insulating film, a first trench emitter electrode inside the second trench through the second insulating film, and a second trench emitter electrode inside the third trench through the third insulating film;
(f) after the step (e), forming a first base region of a second conductive type opposite to the first conductive type inside the first hole barrier region, forming a second base region of the second conductive type inside the second hole barrier region, forming a first floating region of the second conductive type inside the semiconductor substrate located on the other side surface side of both side surfaces of the second trench opposite to one side surface where the first hole barrier region is formed, and forming a second floating region of the second conductive type inside the semiconductor substrate located on the other side surface side of both side surfaces of the third trench opposite to one side surface where the second hole barrier region is formed; and
(g) after the step (f), forming a first emitter region of the first conductive type inside the first base region, and forming a second emitter region of the first conductive type inside the second base region,
wherein each depth of the first floating region and the second floating region from the upper surface of the semiconductor substrate is shallower than each depth of the first trench, the second trench, and the third trench from the upper surface of the semiconductor substrate, and is deeper than each depth of the first base region and the second base region from the upper surface of the semiconductor substrate.

13. The method of manufacturing the semiconductor device according to claim 12,
wherein each impurity concentration of the first floating region and the second floating region is higher than each impurity concentration of the first base region and the second base region.

14. The method of manufacturing the semiconductor device according to claim 11, further comprising a step of:
(h) between the step (b) and the step (c), performing a heat treatment,
wherein the first hole barrier region and the second hole barrier region are diffused by the heat treatment, and
wherein, after the step (c), each depth of the first hole barrier region and the second hole barrier region from the upper surface of the semiconductor substrate is deeper than each depth of the first trench, the second trench and the third trench from the upper surface of the semiconductor substrate.

15. The method of manufacturing the semiconductor device according to claim 11, further comprising steps of:
(i) after the step (g), forming an interlayer insulating film on the upper surface of the semiconductor substrate so as to cover the first trench, the second trench, and the third trench;
(j) after the step (i), forming a first hole penetrating the interlayer insulating film and reaching the first trench emitter electrode, the first base region, and the first emitter region, and forming a second hole penetrating the interlayer insulating film and reaching the second trench emitter electrode, the second base region, and the second emitter region;
(k) after the step (i), forming a third hole penetrating the interlayer insulating film and reaching the trench gate electrode;
(l) after the step (k), forming a first plug inside the first hole, a second plug inside the second hole, and a third plug inside the third hole; and
(m) after the step (l), forming an emitter wiring and a gate wiring on the interlayer insulating film,
wherein the first trench emitter electrode, the first base region, and the first emitter region are electrically connected to the emitter wiring through the first plug,
wherein the second trench emitter electrode, the second base region, and the second emitter region are electrically connected to the emitter wiring through the second plug,
wherein the trench gate electrode is electrically connected to the gate wiring through the third plug, and
wherein each of the first floating region and the second floating region is in an electrically floating state.

16. A semiconductor device including an IGBT including a plurality of cells,
each of the plurality of cells includes:
a trench gate electrode, a first trench emitter electrode and a second trench emitter electrode formed in an n-type semiconductor substrate;
a first base region of a p-type formed inside the semiconductor substrate located between the trench gate electrode and the first trench emitter electrode; and
a second base region of the p-type formed inside the semiconductor substrate located between the trench gate electrode and the second trench emitter electrode,
wherein a floating region of the p-type is formed inside the semiconductor substrate located between the plurality of cells, and
wherein a depth of the floating region is shallower than each depth of the trench gate electrode, the first trench emitter electrode and the second trench emitter electrode, and is deeper than each depth of the first base region and the second base region.

17. The semiconductor device according to claim 16,
wherein each of the plurality of cells further includes:
a first emitter region of an n-type formed inside the first base region;
a second emitter region of the n-type formed inside the second base region;
a first hole barrier region of the n-type formed inside the semiconductor substrate located between the trench gate electrode and the first trench emitter electrode; and
a second hole barrier region of the n-type formed inside the semiconductor substrate located between the trench gate electrode and the second trench emitter electrode,
wherein the first base region is formed inside the first hole barrier region,
wherein the second base region is formed inside the second hole barrier region,
wherein each impurity concentration of the first hole barrier region and the second hole barrier region is higher than an impurity concentration of the semiconductor substrate,
wherein the first base region forms a p-n junction with the first emitter region and the first hole barrier region,
wherein the second base region forms a p-n junction with the second emitter region and the second hole barrier region, and
wherein the floating region forms a p-n junction with the semiconductor substrate.

18. The semiconductor device according to claim 17,
wherein an impurity concentration of the floating region is higher than each impurity concentration of the first base region and the second base region.

19. The semiconductor device according to claim 17, further comprising:
an interlayer insulating film formed on the semiconductor substrate so as to cover the trench gate electrode, the first trench emitter electrode, and the second trench emitter electrode;
a first hole penetrating the interlayer insulating film and reaching the first trench emitter electrode, the first base region, and the first emitter region;
a second hole penetrating the interlayer insulating film and reaching the second trench emitter electrode, the second base region, and the second emitter region;
a third hole penetrating the interlayer insulating film and reaching the trench gate electrode;
a first plug formed inside the first hole;
a second plug formed inside the second hole;
a third plug formed inside the third hole; and
an emitter wiring and a gate wiring formed on the interlayer insulating film,
wherein the first trench emitter electrode, the first base region, and the first emitter region are electrically connected to the emitter wiring through the first plug,
wherein the second trench emitter electrode, the second base region, and the second emitter region are electrically connected to the emitter wiring through the second plug,
wherein the trench gate electrode is electrically connected to the gate wiring through the third plug, and
wherein each of the first floating region and the second floating region is in an electrically floating state.

20. The semiconductor device according to claim 16,
wherein the trench gate electrode, the first trench emitter electrode, and the second trench emitter electrode included in each of the plurality of cells are formed at the same pitch.
